(19) United States
(12) Patent Application Publication
(10) Pub. No.: US 2025/0140711 A1
(43) Pub. Date: May 1, 2025

(54) SEMICONDUCTOR DEVICE

(71) Applicant: Samsung Electronics Co., Ltd., Suwon-si (KR)

(72) Inventors: Byounghoon KIM, Suwon-si (KR); Jihwan SEO, Suwon-si (KR); Sangsu JEONG, Suwon-si (KR); Sungsik PARK, Suwon-si (KR); Giseok SONG, Suwon-si (KR); Hyunju SONG, Suwon-si (KR)

(73) Assignee: Samsung Electronics Co., Ltd., Suwon-si (KR)

(21) Appl. No.: 18/816,266

(22) Filed: Aug. 27, 2024

(30) Foreign Application Priority Data
Oct. 26, 2023 (KR) 10-2023-0145093

(51) Int. Cl. H01L 23/544; H01L 23/528; H01L 29/06; H01L 29/423; H01L 29/775; H01L 29/786

(52) U.S. Cl. CPC H01L 23/544; H01L 23/528; H01L 23/5283; H10D 30/43; H10D 30/6735; H10D 30/6757; H10D 62/121; H01L 2223/54426

(57) ABSTRACT

A semiconductor device may include a substrate including a logic cell region and a key region, an active pattern in the logic cell region, a channel pattern on the active pattern, a plurality of gate electrodes extending on the channel pattern in a first direction and spaced apart from each other in a second direction perpendicular to the first direction, a device separation layer on the key region, and a first key pattern corresponding to the plurality of gate electrodes on the device separation layer.

### CROSS-REFERENCE TO RELATED APPLICATION

This application is based on and claims priority under 35 U.S.C. § 119 to Korean Patent Application No. 10-2023-0145093, filed on Oct. 26, 2023, in the Korean Intellectual Property Office, the disclosure of which is incorporated by reference herein in its entirety.

### BACKGROUND

Inventive concepts relate to a semiconductor device including key patterns and a manufacturing method thereof.

Semiconductor devices are attracting attention as important elements in the electronics industry because of their characteristics such as small size, multifunctionality, and/or low manufacturing cost. Semiconductor devices may be classified into semiconductor memory devices storing logical data, semiconductor logic devices processing logical data, hybrid semiconductor devices including memory elements and logic elements and the like. As the electronics industry is highly developed, there may be an increase in the requirements for characteristics of semiconductor devices. For example, the requirements for high reliability, high speed, and/or multifunctionality for semiconductor devices are more and more increasing. To meet the requirements for these characteristics, the structure within semiconductor devices becomes more complex, and semiconductor devices are also highly integrated.

As semiconductor devices become more highly integrated, the density of patterns formed in a unit area of a substrate increases. In addition, as semiconductor devices become multifunctional and have highly improved performance, the number of layers formed over a substrate also may increase. Accordingly, there is a need to accurately form patterns at designated locations during a manufacturing process of semiconductor devices. Therefore, alignment keys or overlay keys may be used for the alignment between layers stacked on a substrate.

### SUMMARY

Inventive concepts provide a semiconductor device with improved reliability.

Inventive concepts provide a manufacturing method of a semiconductor device with improved overlay measuring performance.

According to an embodiment of inventive concepts, a semiconductor device may include a substrate including a logic cell region and a key region; an active pattern in the logic cell region; a channel pattern on the active pattern; a plurality of gate electrodes extending on the channel pattern in a first direction, the plurality of gate electrodes being spaced apart from each other in a second direction perpendicular to the first direction; a device separation layer on the key region; and first key patterns corresponding to the plurality of gate electrodes on the device separation layer. Each of the first key patterns may include a plurality of first subkey patterns spaced apart from each other in the first direction and extending in the second direction.

According to an embodiment of inventive concepts, a semiconductor device may include a substrate including a key region; a device separation layer on the key region; a plurality of first key patterns on the device separation layer; and a plurality of second key patterns between adjacent first key patterns among the plurality of first key patterns, each of the plurality of second key patterns extending in a first direction, and each of the plurality of first key patterns including a plurality of first subkey patterns spaced apart from each other in the first direction and extending in a second direction, and the second direction may be perpendicular to the first direction; a first spacer on a side wall of a corresponding one of the plurality of first subkey patterns; and a capping pattern on the corresponding one of the plurality of first subkey patterns.

According to an embodiment of inventive concepts, a semiconductor device may include a substrate including a key region; a device separation layer on the key region; a plurality of lower key patterns on the device separation layer; a first interlayer insulating film between the plurality of lower key patterns; a second interlayer insulating film on the plurality of lower key patterns and the first interlayer insulating film; and a plurality of upper key patterns between adjacent lower key patterns among the plurality of lower key patterns, the plurality of upper key patterns extending into the second interlayer insulating film, each of the plurality of upper key patterns extending in a first direction. Each of the plurality of lower key patterns may include a plurality of first subkey patterns spaced apart from each other in the first direction and extending in a second direction, and the second direction may be perpendicular to the first direction.

### BRIEF DESCRIPTION OF THE DRAWINGS

Embodiments will be more clearly understood from the following detailed description taken in conjunction with the accompanying drawings in which:

FIG. 1 is a plan view for describing a semiconductor device according to some embodiments;

FIG. 2A is a plan view for describing a semiconductor device according to an embodiment, illustrating a logic cell region of FIG. 1;

FIG. 2B is a cross-sectional view taken along line A-A′ of FIG. 2A;

FIG. 2C is a cross-sectional view taken along line B-B′ of FIG. 2A;

FIG. 2D is a cross-sectional view taken along line C-C′ of FIG. 2A;

FIG. 2E is a cross-sectional view taken along line D-D′ of FIG. 2A;

FIG. 3A is a plan view illustrating a key region of a semiconductor device according to an embodiment;

FIG. 3B is a cross-sectional view taken along line A-A′ of FIG. 3A;

FIG. 3C is a cross-sectional view taken along line B-B′ of FIG. 3A;

FIGS. 4A and 4B are a plan view and a cross-sectional view illustrating a key region of a semiconductor device according to another embodiment, respectively;

FIGS. 5A and 5B are a plan view and a cross-sectional view illustrating a key region of a semiconductor device according to another embodiment, respectively;

FIGS. 6, 7A, 8, 9, and 10 each are a cross-sectional view taken along line A-A′ of FIG. 5A for describing a manufacturing method of a semiconductor device;

FIG. 7B is a cross-sectional view taken along line B-B′ of FIG. 5A for describing a manufacturing method of a semiconductor device; and

FIGS. 11A and 11B are a plan view and a cross-sectional view illustrating a key region of a semiconductor device according to another embodiment, respectively.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, embodiments are described in detail with reference to the accompanying drawings. The same reference numerals are used for the same elements in the drawings, and redundant descriptions thereof are omitted.

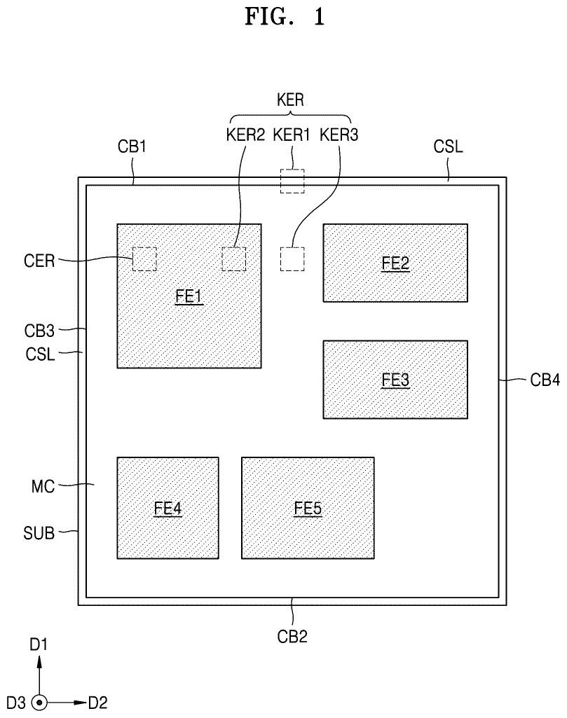

FIG. 1 is a plan view for describing a semiconductor device according to some embodiments. Referring to FIG. 1, the semiconductor device may include a main chip MC and a cut scribe lane CSL surrounding the main chip MC. The main chip MC may include first to fifth functional units FE1 to FE5 over a substrate 100. The substrate 100 may include a diced semiconductor wafer. The substrate 100 may support the first to fifth functional units FE1 to FE5.

The main chip MC may include first to fourth boundaries CB1 to CB4. The first to fourth boundaries CB1 to CB4 may be defined between the cut scribe lane CSL and the main chip MC. The cut scribe lane CSL may surround the first to fourth boundaries CB1 to CB4 of the main chip MC. In an embodiment, the cut scribe lane CSL may include a first key region KER1 adjacent to the first boundary CB1 of the main chip MC. In other words, the first key region KER1 may remain on the cut scribe lane CSL even after a dicing process for a wafer.

Each of the first to fifth functional units FE1 to FE5 may include a functional block (or also referred to as an intellectual property (IP)) constituting an integrated circuit. Each of the first to fifth functional units FE1 to FE5 may include any one of a memory block, an analog logic block, an input/output (I/O) logic block, a central processing unit (CPU) block, and a radio frequency block.

As an example, the first functional unit FE1 may include a logic cell region CER and a second key region KER2. In other words, the key region KER may be provided not only on a scribe lane but also in a functional block. A third key region KER3 may be provided in a region between the first functional unit FE1 and the second functional unit FE2.

The key region KER may include key patterns described below. The key patterns may include an overlay key, an alignment key, or a combination thereof.

Key regions KER according to some embodiments may include first to third key regions KER1, KER2, and KER3, which are positioned in different locations over a semiconductor device. At least one of the first to third key regions KER1, KER2, and KER3 illustrated may be omitted from within a semiconductor device, that is, a semiconductor chip.

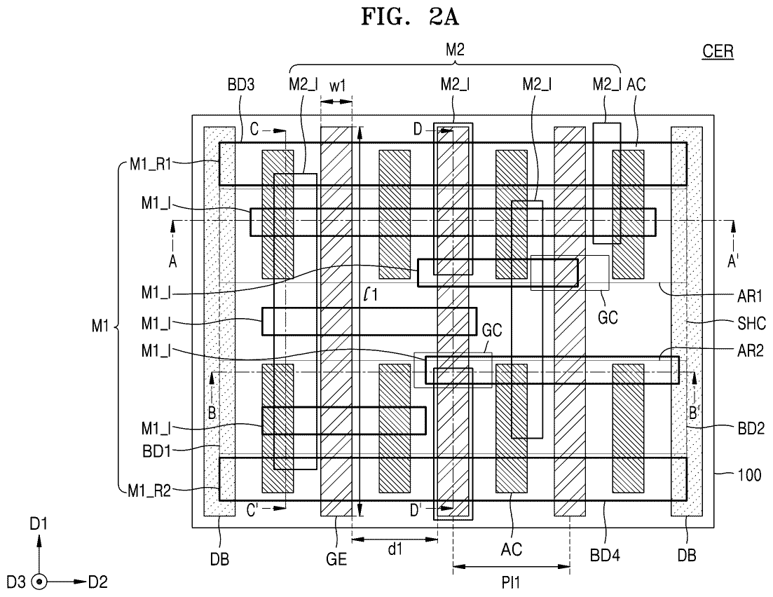

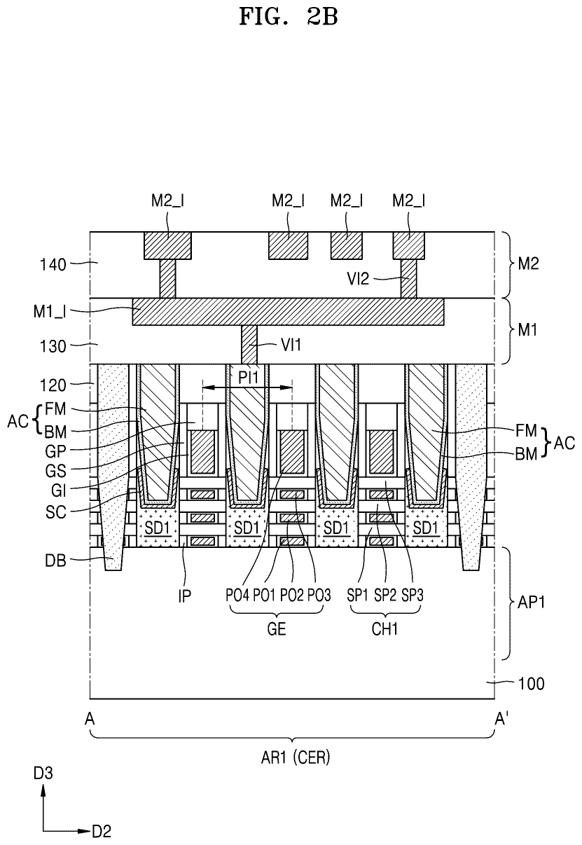

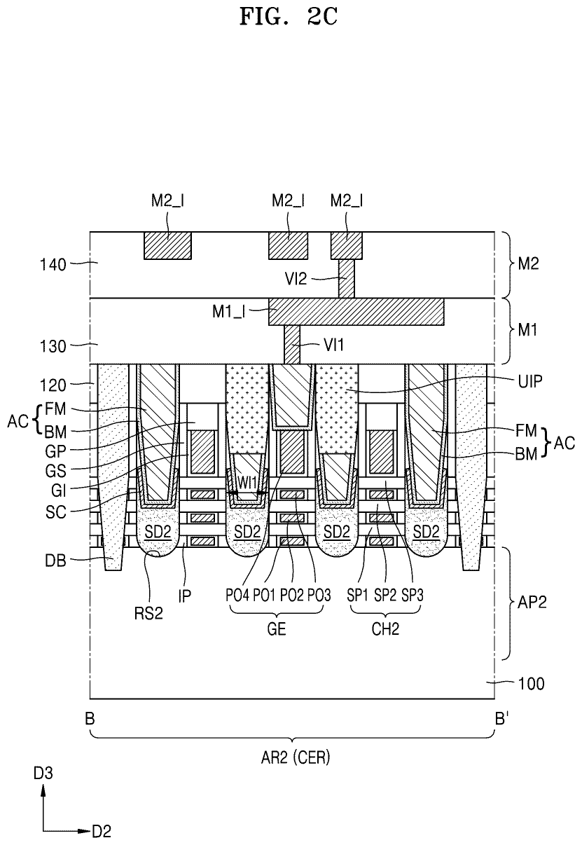

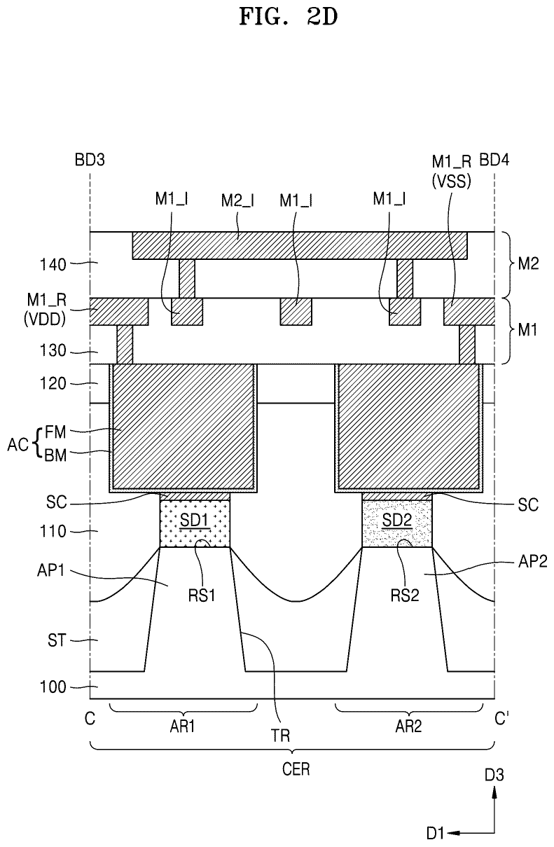

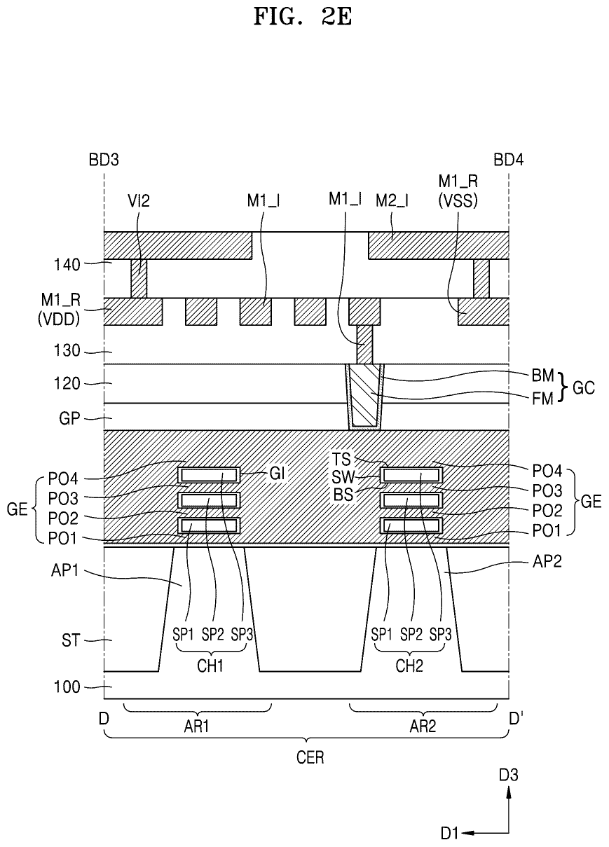

FIG. 2A is a plan view for describing a semiconductor device according to an embodiment, illustrating a logic cell region of FIG. 1. FIGS. 2B to 2E are cross-sectional views taken along lines A-A′, B-B′, C-C′, and D-D′ of FIG. 2A, respectively.

Referring to FIGS. 2A to 2E, a first functional unit FE1 of a semiconductor chip shown in FIG. 1 may include a logic cell region CER. The logic cell region CER may include a logic cell including logic elements (e.g., AND, OR, XOR, XNOR, inverter, etc.) that perform certain functions. A logic cell SHC of the logic cell region CER may include transistors for forming logic elements and wirings connecting the transistors to each other. A substrate 100 may include a semiconductor substrate or a compound semiconductor substrate containing silicon, germanium, silicon-germanium, and the like. As an example, the substrate 100 may include a silicon substrate.

The substrate 100 may include a first active region AR1 and a second active region AR2. Each of the first and second active regions AR1 and AR2 may extend in a second direction D2. In an embodiment, the first active region AR1 may include a P-channel metal-oxide-semiconductor field-effect transistor (PMOSFET) region, and the second active region AR2 may include a N-channel metal-oxide-semiconductor field-effect transistor (NMOSFET) region.

A first active pattern AP1 and a second active pattern AP2 may be defined by a trench TR formed in an upper portion of the substrate 100. The first active pattern AP1 may be provided over the first active region AR1, and the second active pattern AP2 may be provided over the second active region AR2. The first and second active patterns AP1 and AP2 may extend in the second direction D2. As part of the substrate 100, the first and second active patterns AP1 and AP2 may include portions protruding perpendicularly.

A device separation layer ST may be provided over the substrate 100. The device separation layer ST may fill the trench TR. The device separation layer ST may include a silicon oxide film. The device separation layer ST may not cover first and second channel patterns CH1 and CH2 described below.

The first channel pattern CH1 may be provided over the first active pattern AP1. The second channel pattern CH2 may be provided over the second active pattern AP2. The first channel pattern CH1 and the second channel pattern CH2 may each include a first semiconductor pattern SP1, a second semiconductor pattern SP2, and a third semiconductor pattern SP3 that are sequentially stacked. The first to third semiconductor patterns SP1, SP2, and SP3 may be spaced apart from each other in a vertical direction (that is, a third direction D3).

Each of the first to third semiconductor patterns SP1, SP2, and SP3 may include a nano sheet. In other words, each of the first and second channel patterns CH1 and CH2 may include a stack including stacked nano sheets. Each of the first to third semiconductor patterns SP1, SP2, and SP3 may contain silicon (Si), germanium (GE), or silicon-germanium (SiGe). For example, each of the first to third semiconductor patterns SP1, SP2, and SP3 may contain crystalline silicon.

A plurality of first source/drain patterns SD1 may be provided on the first active pattern AP1. A plurality of first recesses RS1 may be formed in an upper portion of the first active pattern AP1. The first source/drain patterns SD1 may be provided in each of the first recesses RS1. The first source/drain patterns SD1 may include impurity regions of a first conductivity type (e.g., p-type). The first channel pattern CH1 may be disposed between a pair of the first source/drain patterns SD1. In other words, the first to third semiconductor patterns SP1, SP2, and SP3 that are stacked may connect the pair of the first source/drain patterns SD1 to each other.

A plurality of second source/drain patterns SD2 may be provided on the second active pattern AP2. A plurality of second recesses RS2 may be formed in an upper portion of the second active pattern AP2. As an example, the second recess RS2 may have a first width WII in the second direction D2. The second source/drain patterns SD2 may be provided in each of the second recesses RS2. The second source/drain patterns SD2 may include impurity regions of a second conductivity type (e.g., n-type). The second channel pattern CH2 may be disposed between a pair of the second source/drain patterns SD2. In other words, the first to third semiconductor patterns SP1, SP2, and SP3 that are stacked may connect the pair of the second source/drain patterns SD2 to each other.

The first and second source/drain patterns SD1 and SD2 may include epitaxial patterns formed through a selective epitaxial growth (SEG) process. As an example, each of the first and second source/drain patterns SD1 and SD2 may have an upper surface that is higher than an upper surface of the third semiconductor pattern SP3. In another example, at least one of the first and second source/drain patterns SD1 and SD2 may have the upper surface that may be positioned at substantially the same level as the upper surface of the third semiconductor pattern SP3.

In an embodiment, the first source/drain patterns SD1 may include a semiconductor element (e.g., SiGe) having a greater lattice constant than a lattice constant of a semiconductor element of the substrate 100. Accordingly, the pair of the first source/drain patterns SD1 may provide compressive stress to the first channel pattern CH1 therebetween. The second source/drain patterns SD2 may include the same semiconductor element (e.g., Si) as the substrate 100.

Each of the first source/drain patterns SD1 may have a side wall which is in an uneven embossing form. In other words, the side wall of the first source/drain pattern SD1 may have a wavy profile. The side wall of the first source/drain pattern SD1 may protrude towards each of first to third inner electrodes PO1, PO2, and PO3 of a gate electrode GE described below.

The gate electrodes GE extending in the first direction D1 across the first and second channel patterns CH1 and CH2 may be provided. In a plan view, the gate electrodes GE may be in a line shape having a length l1 in the first direction D1 and a width WI in the second direction D2. The gate electrodes GE may be arranged at a first pitch PI1 in the second direction D2 (see FIGS. 2A and 2B). Each of the gate electrodes GE may vertically overlap the first and second channel patterns CH1 and CH2.

The gate electrode GE may include the first inner electrode PO1 disposed between the active pattern AP1 or AP2 and the first semiconductor pattern SP1, the second inner electrode PO2 disposed between the first semiconductor pattern SP1 and the second semiconductor pattern SP2, the third inner electrode PO3 disposed between the second semiconductor pattern SP2 and the third semiconductor pattern SP3, and an outer electrode PO4 on the third semiconductor pattern SP3.

Referring to FIG. 2E, the gate electrode GE may be provided over an upper surface TS, a bottom surface BS, and both side walls SW of each of the first to third semiconductor patterns SP1, SP2, and SP3. The gate electrode GE may surround the upper surface TS, the bottom surface BS, and both the side walls SW of each of the first to third semiconductor patterns SP1, SP2, and SP3. In other words, a transistor according to the embodiment may include a three-dimensional field-effect transistor (e.g., a multi-bridge channel FET (MBCFET) or a gate-all-around FET (GAAFET)) in which the gate electrode GE surrounds a channel three-dimensionally.

A pair of gate spacers GS may be located on both side walls of the outer electrode PO4 of the gate electrode GE, respectively. The gate spacers GS may extend in the first direction D1 along the gate electrode GE. The gate spacers GS may have upper surfaces higher than an upper surface of the gate electrode GE. The upper surfaces of the gate spacers GS may be coplanar with an upper surface of a first interlayer insulating film 110 described below. In an embodiment, the gate spacers GS may contain at least one of SiCN, SiCON, and SiN. In another embodiment, the gate spacers GS may include a multi-layer containing at least two of SiCN, SiCON, and SiN.

A gate capping pattern GP may be provided on the gate electrode GE. The gate capping pattern GP may extend in the first direction D1 along the gate electrode GE. The gate capping pattern GP may include a material having an etching selectivity for first and second interlayer insulating films 110 and 120 described below. Specifically, the gate capping pattern GP may contain at least one of SION, SiCN, SiCON, and SiN.

A gate insulating film GI may be disposed between the gate electrode GE and the first channel pattern CH1 and between the gate electrode GE and the second channel pattern CH2. The gate insulating film GI may cover the upper surface TS, the bottom surface BS, and both the side walls SW of each of the first to third semiconductor patterns SP1, SP2, and SP3. The gate insulating film GI may cover an upper surface of the device separation layer ST under the gate electrode GE.

In an embodiment, the gate insulating film GI may include an interface film and a high-k dielectric film. The interface film may include a silicon oxide film or a silicon oxynitride film. The high-k dielectric film may include a high-k dielectric constant material having a higher dielectric constant than a silicon oxide film. As an example, the high-k dielectric film may contain at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In another example, the semiconductor device according to inventive concepts may include a negative capacitance FET (NCFET) using a negative capacitor. For example, the gate insulating film GI may include a ferroelectric material film having ferroelectric characteristics and a paraelectric material film having paraelectric characteristics.

The ferroelectric material film may have a negative capacitance and the paraelectric material film may have a positive capacitance. For example, when two or more capacitors are connected in series and capacitance of each capacitor has a positive value, total capacitance may be lower than each capacitance of each capacitor. However, when at least one of capacitance of two or more capacitors that are connected in series has a negative value, total capacitance may be greater than an absolute value of each capacitance of each capacitor while having a positive value.

When the ferroelectric material film having a negative capacitance is connected in series with the paraelectric material film having a positive capacitance, an overall capacitance value of the ferroelectric material film and the paraelectric material film that are connected in series may increase. Using an increase in the overall capacitance value, a transistor including the ferroelectric material film may have a subthreshold swing (SS) of 60 mV/decade or less at room temperature.

The ferroelectric material film may have ferroelectric characteristics. The ferroelectric material film may contain, for example, at least one of hafnium oxide, hafnium zirconium oxide, barium strontium titanium oxide, barium titanium oxide, and lead zirconium titanium oxide. Here, as an example, hafnium zirconium oxide may be a material in which hafnium oxide is doped with zirconium (Zr). As another example, hafnium zirconium oxide may be a compound of hafnium (Hf), zirconium (Zr), and oxygen (O).

The ferroelectric material film may further include a doped dopant. For example, the dopant may contain at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). According to a ferroelectric material that the ferroelectric material film includes, types of dopants included in the ferroelectric material film may vary.

When the ferroelectric material film contains hafnium oxide, a dopant included in the ferroelectric material film may contain, for example, at least one of gadolinium (Gd), silicon (Si), zirconium (Zr), aluminum (Al), and yttrium (Y).

When the dopant is aluminum (Al), the ferroelectric material film may contain aluminum of about 3 to about 8 atomic % (at %). Here, a proportion of the dopant may be a ratio of aluminum to a sum of hafnium and aluminum.

When the dopant is silicon (Si), the ferroelectric material film may contain silicon of about 2 to about 10 at %. When the dopant is yttrium (Y), the ferroelectric material film may contain yttrium of about 2 to about 10 at %. When the dopant is gadolinium (Gd), the ferroelectric material film may contain gadolinium of about 1 to about 7 at %. When the dopant is zirconium (Zr), the ferroelectric material film may contain zirconium of about 50 to about 80 at %.

The paraelectric material film may have paraelectric characteristics. The paraelectric material film may contain, for example, at least one of silicon oxide and metal oxide having a high-k dielectric constant. The metal oxide contained in the paraelectric material film may include, for example, at least one of hafnium oxide, zirconium oxide, and aluminum oxide, but is not limited thereto.

The ferroelectric material film and the paraelectric material film may include the same material. Although the ferroelectric material film may have ferroelectric characteristics, the paraelectric material film may not have ferroelectric characteristics. For example, when the ferroelectric material film and the paraelectric material film each contain hafnium oxide, a crystal structure of hafnium oxide contained in the ferroelectric material film may differ from a crystal structure of hafnium oxide contained in the paraelectric material film.

The ferroelectric material film may have a thickness possessing the ferroelectric characteristics. The ferroelectric material film may have a thickness of, for example, about 0.5 to 10 nm, but is not limited thereto. Since a threshold thickness exhibiting the ferroelectric characteristics may vary in each ferroelectric material, the thickness of the ferroelectric material film may vary depending on a ferroelectric material thereof.

As an example, the gate insulating film GI may include a single ferroelectric material film. As another example, the gate insulating film GI may include a plurality of ferroelectric material films spaced apart from each other. The gate insulating film GI may have a laminated film structure in which a plurality of ferroelectric material films and a plurality of paraelectric material films are alternately stacked.

Referring back to FIG. 2C, inner spacers IP may be provided on the second active pattern AP2. The inner spacers IP may be disposed between each of the first to third inner electrodes PO1, PO2, and PO3 of the gate electrode GE and the second source/drain pattern SD2, respectively. The inner spacers IP may be in direct contact with the second source/drain pattern SD2. Each of the first to third inner electrodes PO1, PO2, and PO3 of the gate electrode GE may be spaced apart from the second source/drain pattern SD2 due to each of the inner spacers IP.

The gate electrode GE may include a first metal pattern and a second metal pattern on the first metal pattern. The first metal pattern may be provided on the gate insulating film GI and may be adjacent to the first to third semiconductor patterns SP1, SP2, and SP3. The first metal pattern may include a workfunction metal adjusting a threshold voltage of a transistor. Adjusting a thickness and a composition of the first metal pattern may allow to achieve a desired threshold voltage of the transistor. For example, the first to third inner electrodes PO1, PO2, and PO3 of the gate electrode GE may include the first metal pattern which is the workfunction metal.

The first metal pattern may include a metal nitride film. For example, the first metal pattern may include at least one metal selected from a group consisting of titanium (Ti), tantalum (Ta), aluminum (Al), tungsten (W), and molybdenum (Mo) and nitrogen (N). Furthermore, the first metal pattern may further contain carbon (C). The first metal pattern may include a plurality of workfunction metal films that are stacked.

The second metal pattern may include a metal with a low resistance compared to the first metal pattern. For example, the second metal pattern may include at least one metal selected from a group consisting of tungsten (W), aluminum (Al), titanium (Ti), and tantalum (Ta). The outer electrode PO4 of the gate electrode GE may include the first metal pattern and the second metal pattern on the first metal pattern.

The first interlayer insulating film 110 may be provided on the substrate 100. The first interlayer insulating film 110 may cover the gate spacers GS and the first and second source/drain patterns SD1 and SD2. The upper surface of the first interlayer insulating film 100 may be substantially coplanar with an upper surface of the gate capping pattern GP and an upper surface of the gate spacer GS. On the first interlayer insulating film 110, the second interlayer insulating film 120 covering the gate capping pattern GP may be positioned. A third interlayer insulating film 130 may be provided on the second interlayer insulating film 120. A fourth interlayer insulating film 140 may be provided on the third interlayer insulating film 130. As an example, the first to fourth interlayer insulating films 110 to 140 may include a silicon oxide film.

The logic cell SHC may have a first boundary BD1 and a second boundary BD2 facing each other in the second direction D2. The first and second boundaries BD1 and BD2 may extend in the first direction D1. The logic cell SHC may have a third boundary BD3 and a fourth boundary BD4 facing each other in the first direction D1. The third and fourth boundaries BD3 and BD4 may extend in the second direction D2.

A pair of separation structures DB facing each other in the second direction D2 may be provided on both sides of the logic cell SHC. For example, the pair of separation structures DB may be provided on the first and second boundaries BD1 and BD2 of the logic cell SHC, respectively. The separation structures DB may extend parallel to the gate electrodes GE in the first direction D1. A pitch between the separation structure DB and the gate electrode GE adjacent thereto may be substantially the same as the first pitch PI1.

The separation structure DB may pass through the gate capping pattern GP and the gate electrode GE and extend into the first and second active patterns AP1 and AP2. The separation structure DB may pass through an upper portion of each of the first and second active patterns AP1 and AP2. The separation structure DB may electrically separate an active region of the logic cell SHC from an active region of another adjacent cell. In other words, the separation structure DB may include a single diffusion break (SDB).

Active contacts AC may be provided, which pass through the first and second interlayer insulating films 110 and 120 and are electrically connected to the first and second source/drain patterns SD1 and SD2, respectively. A pair of active contacts AC may be provided on both sides of the gate electrodes GE, respectively. In a plan view, each of the active contacts AC may have a bar shape extending in the first direction D1.

The active contact AC may be a self-aligned contact. In other words, the active contact AC may be formed in a self-aligned manner using the gate capping pattern GP and the gate spacer GS. For example, the active contact AC may cover at least a portion of a side wall of the gate spacer GS. Although not shown, the active contact AC may cover a portion of the upper surface of the gate capping pattern GP.

The active contacts AC may be arranged at the first pitch PI1 in the second direction D2. In other words, a pitch between the active contacts AC may be substantially the same as the first pitch PI1 between the gate electrodes GE.

A metal-semiconductor compound film SC, for example, a silicide film may be disposed between the active contact AC and the first source/drain pattern SD1 and between the active contact AC and the second source/drain pattern SD2, respectively. The active contact AC may be electrically connected to the first and second source/drain patterns SD1 and SD2 through the metal-semiconductor compound film SC. For example, the metal-semiconductor compound film SC may contain at least one of titanium-silicide, tantalum-silicide, tungsten-silicide, nickel-silicide, and cobalt-silicide.

Gate contacts GC may be provided, which are electrically connected to each of the gate electrodes GE, passing through the second interlayer insulating film 120 and the gate capping pattern GP. In a plan view, the gate contacts GC may be located overlapping each of the first active region AR1 and the second active region AR2. As an example, each of the gate contacts GC may be provided on the second active pattern AP2 (see FIG. 2C).

In an embodiment, referring to FIG. 2C, an upper portion of the active contact AC adjacent to the gate contact GC may be filled with an upper insulating pattern UIP. A bottom surface of the upper insulating pattern UIP may be lower than a bottom surface of the gate contact GC. In other words, an upper surface of the active contact AC adjacent to the gate contact GC may come down lower than the bottom surface of the gate contact GC due to the upper insulating pattern UIP. Accordingly, it may be possible to prevent an occurrence of a short circuit due to the gate contact GC contacting the active contact AC adjacent thereto.

Each of the active contact AC and the gate contact GC may include a conductive pattern FM and a barrier pattern BM surrounding the conductive pattern FM. For example, the conductive pattern FM may include at least one metal of aluminum, copper, tungsten, molybdenum, and cobalt. The barrier pattern BM may cover side walls and a bottom surface of the conductive pattern FM. The barrier pattern BM may include a metal film/metal nitride film. The metal film may contain at least one of titanium, tantalum, tungsten, nickel, cobalt, and platinum. The metal nitride film may include at least one of a titanium nitride film (TiN), a tantalum nitride film (TaN), a tungsten nitride film (WN), a nickel nitride film (NiN), a cobalt nitride film (CON), and a platinum nitride film (PtN).

A first wiring layer M1 may be provided within the third interlayer insulating film 130. For example, the first wiring layer M1 may include a first power line M1_R1, a second power line M1_R2, and first lines M1_I. Each of the lines M1_R1, M1_R2, and M1_I of the first wiring layer M1 may extend parallel to each other in the second direction D2.

Specifically, the first and second power lines M1_R1 and M1_R2 may be provided on the third and fourth boundaries BD3 and BD4 of the logic cell SHC, respectively. The first power line M1_R1 may extend in the second direction D2 along the third boundary BD3. The second power line M1_R2 may extend in the second direction D2 along the fourth boundary BD4.

The first lines M1_I of the first wiring layer M1 may be located between the first and second power lines M1_R1 and M1_R2. The first lines M1_I of the first wiring layer M1 may be arranged in the first direction D1 at a preset pitch. As an example, a pitch between the first lines M1_I may be smaller than the first pitch PI1. A line width w2 of each of the first lines M1_I may be smaller than a line width w2 of each of the first and second power lines M1_R1 and M1_R2.

The first wiring layer M1 may further include first vias VI1. The first vias VI1 may be provided under each of the lines M1_R1, M1_R2, and M1_I of the first wiring layer M1. The active contact AC and each of the lines of the first wiring layer M1 may be electrically connected to each other through each of the first vias VI1. The gate contact GC and each of the lines of the first wiring layer M1 may be electrically connected to each other through each of the first vias VI1.

The line of the first wiring layer M1 and the first via VI1 thereunder may be separately formed through separate processes. In other words, each of the line of the first wiring layer M1 and the first via VI1 may be formed through a single damascene process. The semiconductor device according to the embodiment may be formed using a process of less than 20 nm.

A second wiring layer M2 may be provided within the fourth interlayer insulating film 140. The second wiring layer M2 may include a plurality of second lines M2_I. Each of the second lines M2_I of the second wiring layer M2 may have a line shape or a bar shape extending in the first direction D1. In other words, the second lines M2_I may extend parallel to each other in the first direction D1.

The second wiring layer M2 may further include second vias VI2 provided under each of the second lines M2_I. The line of the first wiring layer M1 and the line of the second wiring layer M2 may be electrically connected to each other through the second via VI2. As an example, the line of the second wiring layer M2 and the second via VI2 thereunder may be formed together through a dual damascene process.

The line of the first wiring layer M1 and the line of the second wiring layer M2 may include the same or different conductive materials. For example, the line of the first wiring layer M1 and the line of the second wiring layer M2 may include at least one metal material selected from among aluminum, copper, tungsten, molybdenum, ruthenium, and cobalt. Although not shown, stacked metal layers (e.g., M3, M4, M5, etc.) may be additionally located on the fourth interlayer insulating film 140. Each of the stacked metal layers may include lines for routing between cells.

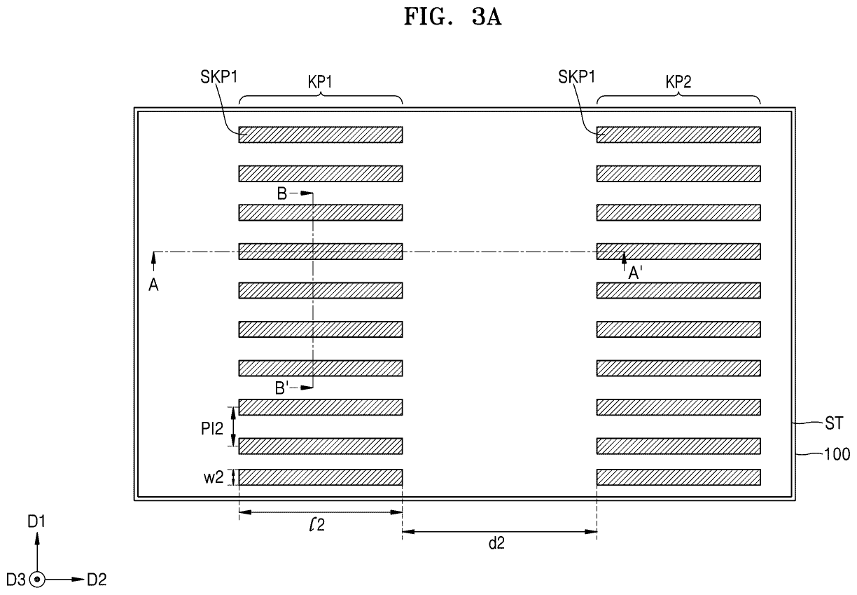

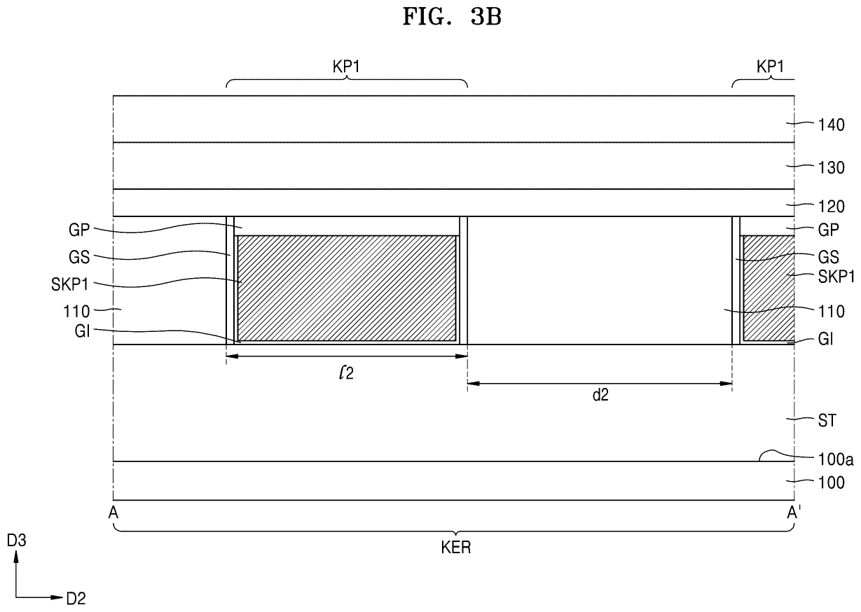

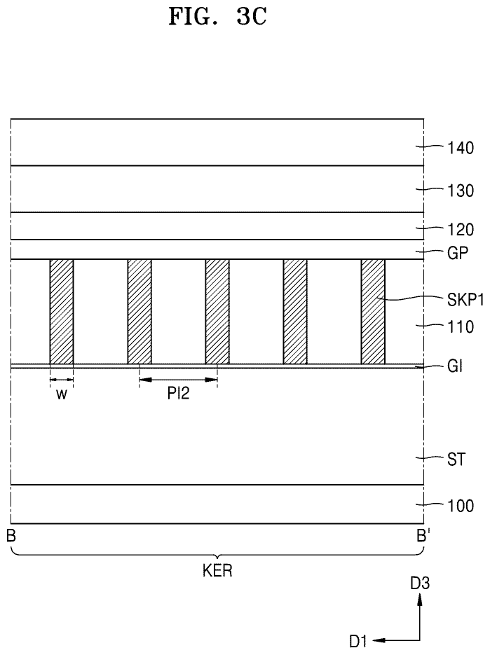

FIG. 3A is a plan view illustrating a key region KER of a semiconductor device of FIG. 1 according to an embodiment, FIG. 3B is a cross-sectional view taken along line A-A′ of FIG. 3A, and FIG. 3C is a cross-sectional view taken along line B-B′ of FIG. 3A.

Any one key region KER of first to third key regions KER1, KER2, and KER3 of a semiconductor chip shown in FIG. 1 is illustrated in FIG. 3A. For example, the key region KER of FIG. 3A may represent the first key region KER1 in the cut scribe lane CSL of FIG. 1. Alternatively, the cut scribe lane CSL may include only a portion of the first key region KER1 therein.

The key region KER may include one or more key patterns KP1 that are used in a manufacturing process of a semiconductor chip. The key pattern KP1 may include an overlay key, an alignment key, or a combination thereof.

Referring to FIGS. 3A to 3C, first key patterns KP1 may be located in the key region KER. Each of the first key patterns KP1 may correspond to a plurality of gate electrodes GE in a logic cell SHC. That is, a spacing d2 between the first key patterns KP1 that, among the first key patterns KP1, are neighboring in a second direction D2 may correspond to a spacing between the gate electrodes GE included in a neighboring unit cell. For example, the spacing d2 between the first key patterns KP1 may be substantially the same as the spacing between the gate electrodes GE included in neighboring cells. In a plan view including a first direction D1 and the second direction D2, a size of a cross-section of one first key pattern KP1 may correspond to a size of a cross-section of the plurality of gate electrodes GE included in one cell. For example, the size of the cross-section of the one first key pattern KP1 may be substantially the same as the size of the cross-section of the plurality of gate electrodes GE included in one cell.

Each of the first key patterns KP1 may include a plurality of first subkey patterns SKP1. The plurality of first subkey patterns SKP1 may be spaced apart from each other in the first direction D1 and extend in the second direction D2. The plurality of first subkey patterns SKP1 may be arranged at a second pitch PI2 in the first direction D1. A ratio of a length l2 to a width w2 of the first subkey pattern SKP1 may be smaller than a ratio of a length l1 to a width w1 of the gate electrode GE. For example, the ratio of the length l2 to the width w2 of the first subkey pattern SKP1 may be equal to or less than ½ of the ratio of the length l1 to the width w1 of the gate electrode GE.

The length l2 of the first subkey pattern SKP1 may be greater than the first pitch PI1 between the plurality of gate electrodes GE. For example, the length l2 of the first subkey pattern SKP1 may exceed 2 times the first pitch PI1 between the plurality of gate electrodes GE. Alternatively, the length l2 of the first subkey pattern SKP1 may be substantially the same as a sum of n times (where n is an integer between about 2 and about 6) the first pitch PI1 between the plurality of gate electrodes GE and the width w1 of the gate electrode GE. For example, when three gate electrodes GE are included in one unit cell, the length l2 of the first subkey pattern SKP1 may be substantially the same as a sum of three times a pitch between the gate electrodes GE and the width w1 of the gate electrode GE.

The width w2 of the first subkey pattern SKP1 may be equal to or less than the width w1 of the gate electrode GE. The length l1 of the gate electrode GE may exceed m times the second pitch PI2 between the first subkey patterns SKP1. For example, a sum of m times (where m is an integer of 5 and more) the second pitch PI2 between the first subkey patterns SKP1 and the width w2 of the first subkey pattern SKP1 may be substantially the same as the length l1 of the gate electrode GE.

The first key patterns KP1 may be provided with a device separation layer ST in the key region KER of a substrate 100. In the key region KER, the first and second active patterns AP1 and AP2 of the logic cell region CER of FIGS. 2A to 2E described on may be omitted.

A plurality of the first subkey patterns SKP1 extending in the second direction D2 may be provided on the device separation layer ST. The first subkey patterns SKP1 may be simultaneously formed with the gate electrodes GE in the logic cell region CER aforementioned.

As described above, the first subkey patterns SKP1 may be arranged at the second pitch PI2 in the first direction D1. The second pitch PI2 may be smaller than the first pitch PI1 between the gate electrodes GE. In an embodiment, the width w2 of the first subkey pattern SKP1 in the first direction D1 may exceed two times the pitch between the gate electrodes GE in the logic cell region CER. The first to third inner electrodes PO1 to PO3 of the gate electrode GE described above may be omitted from the first subkey pattern SKP1.

A pair of gate spacers GS may be located above both side walls of the first subkey pattern SKP1, respectively. The descriptions of the gate spacers GS may be the same as the descriptions of the gate spacers GS in the logic cell region CER aforementioned.

A gate capping pattern GP may be provided on the first subkey pattern SKP1. The descriptions of the gate capping pattern GP may be the same as the descriptions of the gate capping pattern GP in the logic cell region CER aforementioned.

A gate insulating film GI may be disposed between the first subkey pattern SKP1 and the device separation layer ST and between the first subkey pattern SKP1 and the gate spacers GS. The descriptions of the gate insulating film GI may be the same as the descriptions of the gate insulating film GI in the logic cell region CER aforementioned.

First to fourth interlayer insulating films 110 to 140 may be provided in the key region KER of the substrate 100. The descriptions of the first to fourth interlayer insulating films 110 to 140 may be the same as the descriptions of the first to fourth interlayer insulating films 110 to 140 in the logic cell region CER aforementioned.

Using one sizable key as a key corresponding to the plurality of gate electrodes GE may cause side effects such as defects. In addition, as sizes of logic cells and the like decrease, applying sizable keys may not be suitable for design rules, resulting in needs for keys including a plurality of fine patterns. Meanwhile, since using keys having a line-and-space pattern corresponding to an arrangement direction of the gate electrode GE may cause intervals of the keys and a pitch between subkeys included in the keys to be not uniform, a distribution of the keys may not be uniform. In particular, patterns of edges of the keys may be formed with a low distribution, and, in a worse case, a shape of the keys may be altered, resulting in an occurrence of a process defect. An increase in pattern noise due to these defective keys may deteriorate overlay measuring performance.

Since a first key pattern KP1 according to an embodiment may include a plurality of first subkey patterns SKP1 extending in an arrangement direction of the gate electrode GE, that is, the second direction D2, a distribution imbalance of the first key pattern KP1 may be resolved. In addition, the first subkey patterns SKP1 having a uniform length l2 in an overlay scan direction may provide a decrease in the pattern noise and an improvement of the overlay measuring performance.

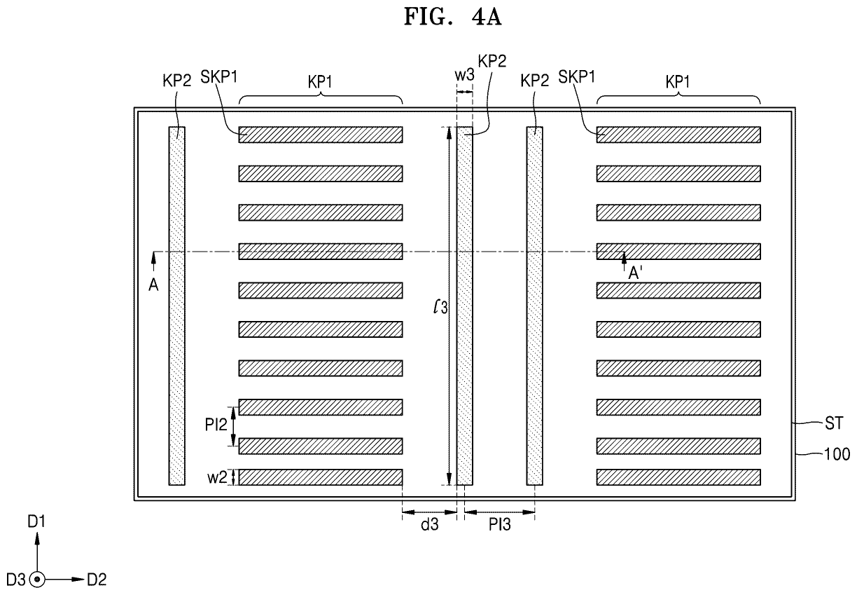

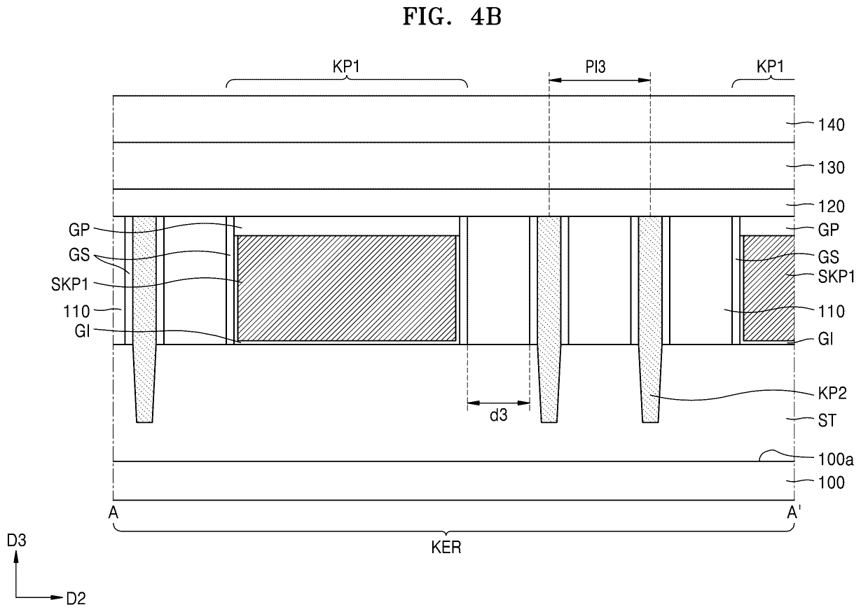

FIG. 4A is a plan view illustrating a key region KER of a semiconductor device according to another embodiment, and FIG. 4B is a cross-sectional view taken along line A-A′ of FIG. 4A. Detailed descriptions of repeated technical features as those given with reference to FIGS. 3A and 3B are omitted, and the differences from the above descriptions are described in detail.

Referring to FIGS. 4A and 4B, a plurality of second key patterns KP2 may be further located between first key patterns KP1 that are neighboring. For example, two second key patterns KP2 may be located between neighboring first key patterns KP1. In another expression, the two second key patterns KP2 may be located in the key region KER with the first key pattern KP1 therebetween.

In a plan view including a first direction D1 and a second direction D2, the second key patterns KP2 may be in a shape of a line extending in the first direction D1. In addition, each of the second key patterns KP2 may extend into a device separation layer ST in a third direction D3 perpendicular to the first direction D1 and the second direction D2.

The second key pattern KP2 may correspond to the separation structure DB described above with references. For example, the second key pattern KP2 may be substantially the same as the separation structure DB described above with references. The second key pattern KP2 may include an overlay key of the separation structure DB. The second key patterns KP2 may be simultaneously formed with the separation structures DB in the logic cell region CER aforementioned.

Specifically, a width w3 and a length l3 of the second key pattern KP2 may be substantially the same as a width and a length of the separation structure DB, and a pitch PI3 between the second key patterns KP2 that are consecutively arranged may be the same as a pitch of the separation structures DB. The pitch PI3 between the consecutively arranged second key patterns KP2 may be the same as the pitch of the separation structures DB. In addition, a spacing d3 between a first subkey pattern SKP1 and the second key pattern KP2 that are arranged to be adjacent to each other may be substantially the same as a spacing d1 between gate electrodes GE. In addition, the width w3 and the length l3 of the second key pattern KP2 may be substantially the same as a width w1 and a length l1 of the gate electrode GE.

In a comparison between the first subkey pattern SKP1 and the second key pattern KP2, a ratio of a length l2 to a width w2 of the first subkey pattern SKP1 may be smaller than a ratio of the length l3 to the width w3 of the second key pattern KP2. For example, the ratio of the length l2 to the width w2 of the first subkey pattern SKP1 may be equal to or less than ½ of the ratio of the length l3 to the width w3 of the second key pattern KP2.

The length l2 of the first subkey pattern SKP1 may be greater than the pitch PI3 between the consecutively arranged second key patterns KP2. For example, the length l2 of the first subkey pattern SKP1 may exceed two times the third pitch PI3 between the consecutively arranged second key patterns KP2. Alternatively, the length l2 of the first subkey pattern SKP1 may be substantially the same as a sum of n times (where n is an integer between about 2 and about 6) the third pitch PI3 between the consecutively arranged second key patterns KP2 and the width w3 of the second key patterns KP2.

The width w2 of the first subkey pattern SKP1 may be equal to or less than the width w3 of the second key patterns KP2. The length l3 of the second key patterns KP2 may exceed m times the second pitch PI2 between the first subkey patterns SKP1. For example, a sum of m times (where m is an integer of 5 or more) the second pitch PI2 between the first subkey patterns SKP1 and the width w2 of the first subkey pattern SKP1 may be substantially the same as the length l3 of the second key pattern KP2.

A pair of gate spacers GS may be located on both side walls of each of the second key patterns KP2, respectively. A pair of gate spacers GS may be located on both side walls of each of the first subkey patterns SKP1, respectively. The descriptions of the gate spacers GS may be the same as the descriptions of the gate spacers GS in the logic cell region CER aforementioned. An upper surface of the second key pattern KP2 may be coplanar with an upper surface of a gate capping pattern GP on the first subkey pattern SKP1.

A bottom of the second key pattern KP2 may be located higher than a front surface 100a of a substrate 100. In other words, a level of the bottom of the second key pattern KP2 may be higher than a level of the front surface 100a of the substrate 100. The device separation layer ST may be disposed between the bottom of the second key pattern KP2 and the front surface 100a of the substrate 100.

In an embodiment, each of second key patterns KP2 may include single diffusion breaks. In other words, the second key pattern KP2 may include a first single diffusion break SDB1 and a second single diffusion break SDB2 that are spaced apart from each other in the second direction D2. A first key pattern KP1 may be located between the first single diffusion break SDB1 and the second single diffusion break SDB2. A spacing d3 between the first single diffusion break SDB1 and the first key pattern KP1 and a spacing d3 between the second single diffusion break SDB2 and the first key pattern KP1 may be substantially the same as a spacing d1 between gate electrodes GE.

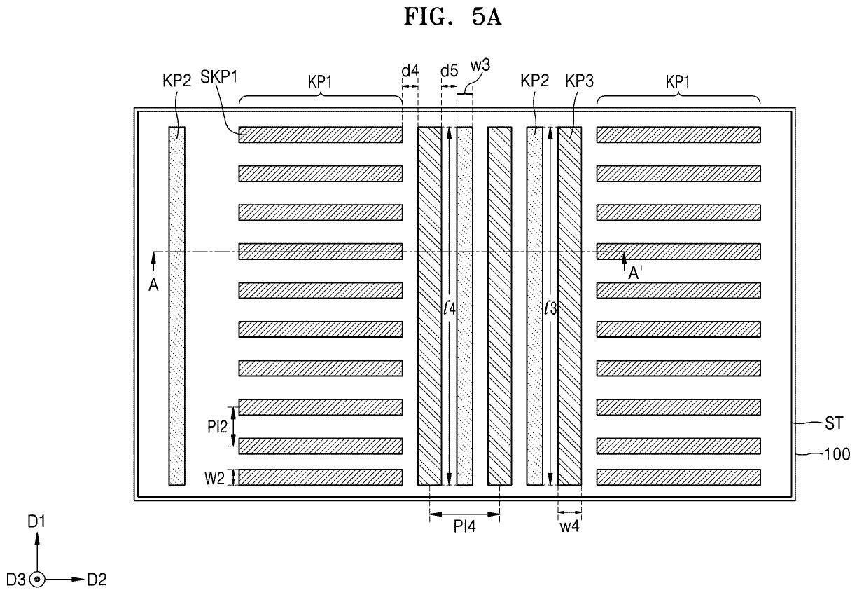

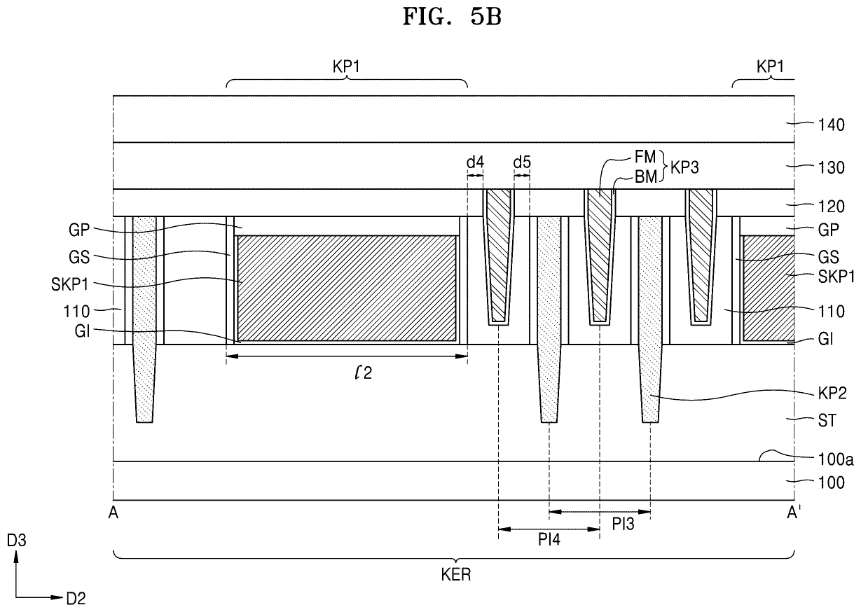

FIG. 5A is a plan view illustrating a key region KER of a semiconductor device according to another embodiment and FIG. 5B is a cross-sectional view taken along line A-A′ of FIG. 5A. Detailed descriptions of repeated technical features as those given with reference to FIGS. 3A, 3B, 4A, and 4B are omitted, and the differences from the above descriptions are described in detail.

Referring to FIGS. 5A and 5B, first key patterns KP1, second key patterns KP2, and third key patterns KP3 may be located in the key region KER. The first key patterns KP1 may include a lower key structure. The third key patterns KP3 may include an upper key structure. In an embodiment, the first key patterns KP1 may include a lower overlay key and the third key patterns KP3 may include an upper overlay key. The first key patterns KP1 and the third key patterns KP3 may be aligned with each other, thereby determining whether a lower layer and an upper layer are aligned. Since the first key pattern KP1 and the second key pattern KP2 are described above, the detailed descriptions thereof will be omitted.

A plurality of the third key patterns KP3 may be located between the first key patterns KP1 that are neighboring in a second direction D2. In the drawings, three of the third key patterns KP3 are shown between the neighboring first key patterns KP1, but are not limited thereto. In a plan view including a first direction D1 and the second direction D2, the plurality of the third key patterns KP3 may be in a shape of a line extending in the first direction D1 and spaced apart from each other in the second direction D2. The third key patterns KP3 may be arranged at a third pitch PI4 in the second direction D2. A third pitch PI4 between the third key patterns KP3 may be substantially the same as or different from a pitch PI1 between gate electrodes GE.

A first subkey pattern SKP1 and the third key pattern KP3 may be adjacent to each other in the second direction D2. A spacing d4 between the first subkey pattern SKP1 and the third key pattern KP3 that are adjacent to each other may be smaller than the pitch PI1 between gate electrodes GE or the third pitch PI4 between the third key patterns KP3. The second key pattern KP2 and the third key pattern KP3 may be adjacent to each other in the second direction D2. A spacing d5 between the second key pattern KP2 and the third key pattern KP3 that are adjacent to each other may be smaller than the pitch PI1 between gate electrodes GE or the third pitch PI4 between the third key patterns KP3.

The plurality of the third key patterns KP3 may pass through first and second interlayer insulating films 110 and 120 and extend towards a substrate 100. Each of the third key patterns KP3 may include a conductive pattern FM and a barrier pattern BM surrounding the conductive pattern FM. The third key patterns KP3 may be simultaneously formed with active contacts AC. In other words, the descriptions of the third key pattern KP3 may be the same as the descriptions of the active contacts AC in the logic cell region CER aforementioned.

In an embodiment, an upper surface of the third key pattern KP3 may be higher than an upper surface of the first subkey pattern SKP1. A bottom surface of the third key pattern KP3 may be higher than a bottom surface of the first subkey pattern SKP1.

A process measuring an alignment state of patterns on a semiconductor substrate may be performed through an overlay measurement process. Through overlay measurement, it may be determined whether the third key patterns KP3 located on an upper layer are correctly aligned and formed based on the first key pattern KP1 located on a lower layer. According to an embodiment, the first key pattern KP1 may include a diffraction base overlay key.

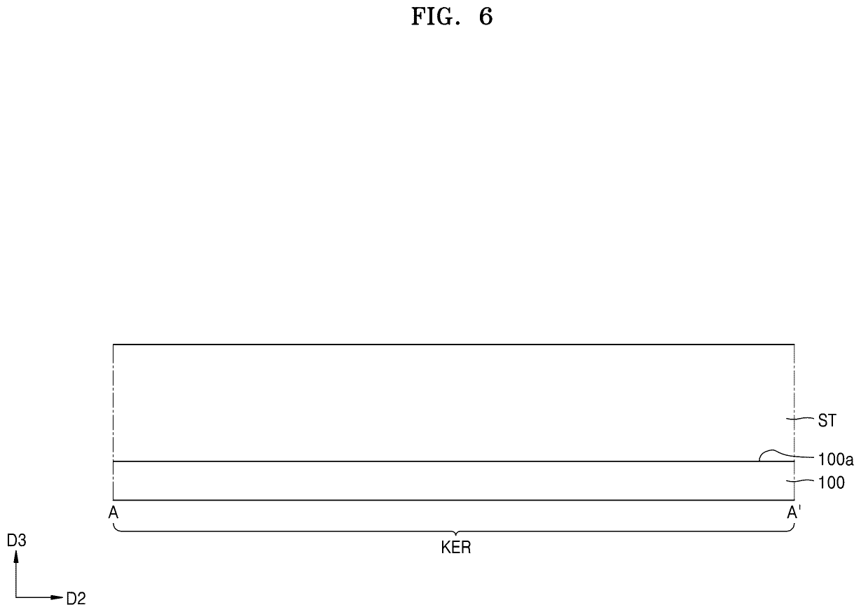

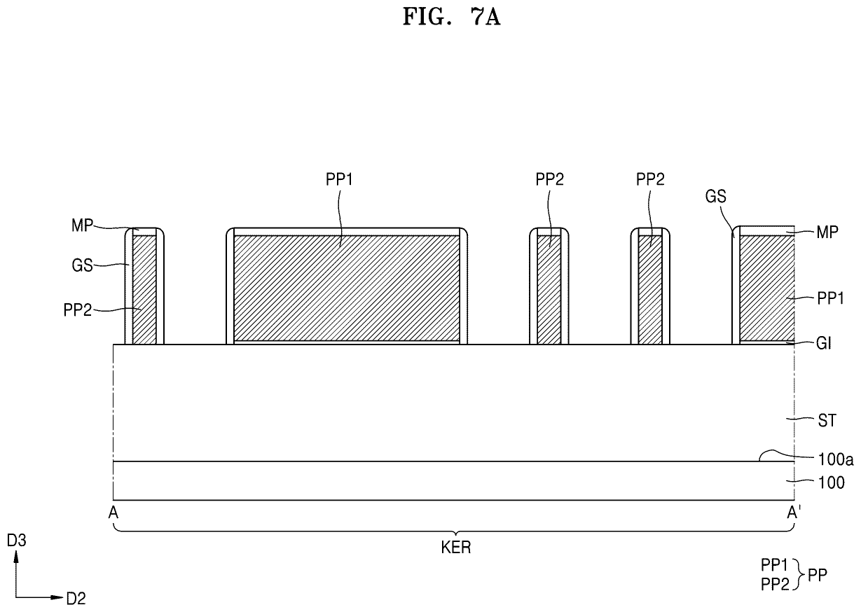

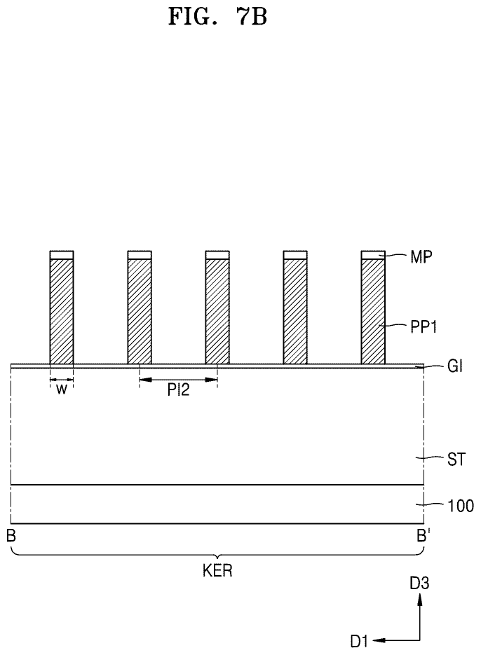

FIGS. 6, 7A, 8, 9, and 10 are cross-sectional views taken along line A-A′ of FIG. 5A for describing a manufacturing method of a semiconductor device and FIG. 7B is a cross-sectional view taken along line B-B′ of FIG. 5A for describing the manufacturing method of the semiconductor device.

Referring to FIG. 6, a substrate 100 including a key region KER may be provided. For example, the substrate 100 may be a silicon wafer. A device separation layer ST may be formed on the substrate 100. The device separation layer ST may include an insulating material such as a silicon oxide film. The device separation layer ST may be formed on a substrate 100. In other words, the substrate 100 of the key region KER may be completely covered by the device separation layer ST.

Referring to FIGS. 7A and 7B, sacrificial patterns PP may be formed on the device separation layer ST. Among the sacrificial patterns PP1 and PP2, first sacrificial patterns PP1 may be in a shape of a line spaced apart from each other in a first direction D1 and extending in a second direction D2. The first sacrificial patterns PP1 according to inventive concepts may be formed in an array shape having a uniform pattern density. The first sacrificial patterns PP1 may be replaced with first subkey patterns SKP1 described below. Among the sacrificial patterns PP1 and PP2, second sacrificial patterns PP2 may be in a shape of a line spaced apart from each other in the second direction D2. The second sacrificial patterns PP2 may be replaced with second patterns KP2 described below. The first sacrificial patterns PP1 may have a width w in the first direction D1 and may be separated by a pitch P12.

Specifically, forming the sacrificial patterns PP1 and PP2 may include forming a sacrificial film on the front surface of the substrate 100, forming hard mask patterns MP on the sacrificial film, and patterning the sacrificial film using the hard mask patterns MP as an etching mask. The sacrificial film may contain polysilicon.

According to an embodiment, a process of forming the hard mask patterns MP may include a lithography process using extreme ultraviolet (EUV). In this specification, EUV may refer to ultraviolet having a wavelength between about 4 nm and about 124 nm, specifically a wavelength between about 4 nm and 20 nm, and more specifically a wavelength of 13.5 nm. EUV may refer to light having an energy between about 6.21 ev and about 124 ev, specifically between about 90 ev and about 95 cv.

The lithography process using EUV may include exposure and development processes using EUV irradiated onto a photoresist film. As an example, the photoresist film may include an organic photoresist containing an organic polymer such as polyhydroxy styrene. The organic photoresist may further include a photosensitive compound that reacts to EUV. The organic photoresist may further include a material with a high EUV absorption rate, for example, an organometallic material, an iodine-containing material, or a fluorine-containing material. As another example, the photoresist film may include an inorganic photoresist containing an inorganic material such as tin oxide.

The photoresist film may be formed with a relatively thin thickness. Photoresist patterns may be formed by developing the photoresist film exposed to EUV. In a plan view, the photoresist patterns may have a line shape extending in one direction, an island shape, a zigzag shape, a honeycomb shape, or a circle shape, but are not limited to these examples.

Using the photoresist patterns as an etching mask, the hard mask patterns MP may be formed by patterning one or more mask layers that are stacked under the photoresist patterns. Using the hard mask patterns MP as an etching mask, desired sacrificial patterns PP may be formed on the substrate 100 by patterning a target layer (that is, the sacrificial layer).

In another embodiment, a process of forming the hard mask patterns MP may include a multi patterning technique (MPT). As an example, the hard mask patterns MP may be formed using two or more photo masks. As another example, the hard mask patterns MP may be formed using a double patterning technique (DPT) or a quadruple patterning technique (QPT).

A pair of gate spacers GS may be formed on both side walls of the sacrificial patterns PP1 and PP2, respectively. Forming the gate spacers GS may include conformally forming a gate spacer film on the front surface of the substrate 100, and anisotropically etching the gate spacer film. In an embodiment, each of the gate spacers GS may include a multi-film including at least two films.

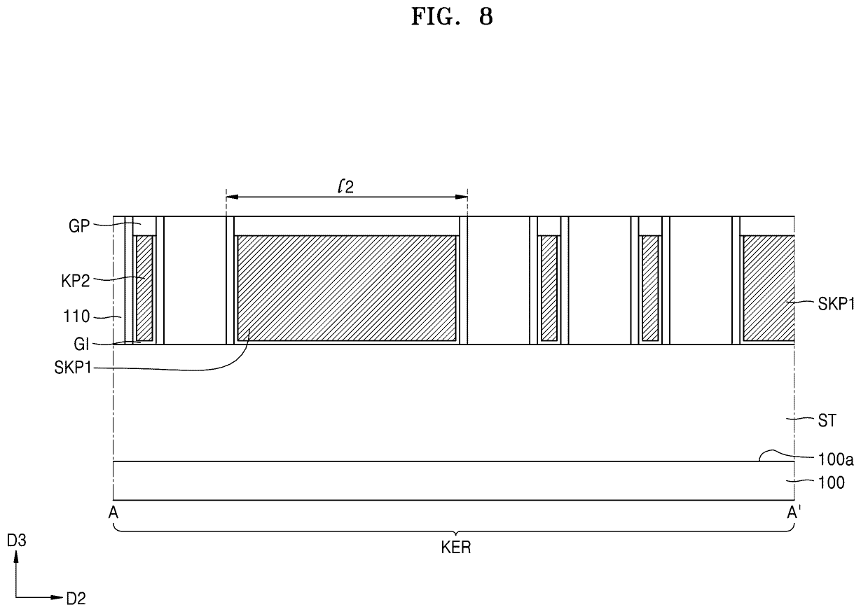

Referring to FIG. 8, a first interlayer insulating film 110 covering a device separation layer ST, hard mask patterns MP, and gate spacers GS may be formed. As an example, the first interlayer insulating film 110 may include a silicon oxide film.

The first interlayer insulating film 110 may be planarized until upper surfaces of sacrificial patterns PP1 and PP2 are exposed. The planarization of the first interlayer insulating film 110 may be performed using etch back or chemical mechanical polishing (CMP) processes. During the planarization process, all the hard mask patterns MP may be removed. As a result, an upper surface of the first interlayer insulating film 110 may be coplanar with the upper surfaces of the sacrificial patterns PP1 and PP2 and upper surfaces of the gate spacers GS.

Each of the first sacrificial patterns PP1 may be replaced with first subkey patterns SKP1. The first subkey patterns SKP1 may be formed to be arranged with a pitch PI2 in a first direction D1. Specifically, the first sacrificial patterns PP1 that are exposed may be selectively removed. Removing the first sacrificial patterns PP1 may include a wet etching using an etchant that selectively etches polysilicon.

A gate insulating film GI may be formed in an empty region from which the first sacrificial patterns PP1 have been removed. For example, the gate insulating film GI may include an interfacial film and a high-k dielectric film that are sequentially stacked. By filling a portion on the gate insulating film GI with metal, each of the first subkey patterns SKP1 may be formed. The first subkey pattern SKP1 may be recessed, resulting in a decrease in a height thereof. A gate capping pattern GP may be formed on the recessed first subkey pattern SKP1. The gate electrodes GE described with reference to FIGS. 2A to 2E may be formed together with the first subkey patterns SKP 1.

Ten of the first subkey patterns SKP1 that are spaced apart from each other in a first direction D1 may form one key pattern KP1. In an embodiment, the first key pattern KP1 may be used as a lower overlay key.

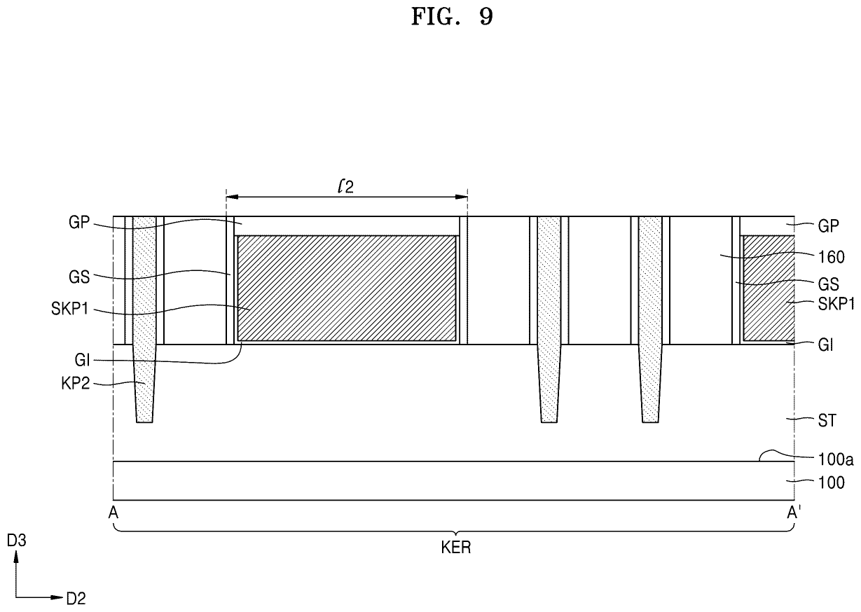

Referring to FIG. 9, a second key pattern KP2 passing through second sacrificial patterns PP2 may be formed.

Forming the second key pattern KP2 may include forming a mask, on a first interlayer insulating film 110, exposing the second sacrificial patterns PP2 to be removed, anisotropically etching the exposed second sacrificial patterns PP2 by using the mask as an etching mask, and filling, with an insulating material, a trench from which the second sacrificial patterns PP2 have been removed.

A second interlayer insulating film 120 may be formed on the first interlayer insulating film 110. The second interlayer insulating film 120 may include a silicon oxide film. Third key patterns KP3 passing through the second interlayer insulating film 120 and the first interlayer insulating film 110 may be formed. The active contacts AC described with reference to FIGS. 2A to 2E may be formed together with the third key patterns KP3.

A spacing d4 between the first key pattern KP1 and the third key pattern KP3 and a spacing d5 between the second key pattern KP2 and the third key pattern KP3 may be smaller than a spacing d1 between gate electrodes GE. Alternatively, the spacing d4 between the first key pattern KP1 and the third key pattern KP3 may be substantially the same as the spacing d5 between the second key pattern KP2 and the third key pattern KP3. One third key pattern KP3 among a plurality of the third key patterns KP3 may be disposed between the first key pattern KP1 and the second key pattern KP2 adjacent to each other. In an embodiment, the third key pattern KP3 may be used as an upper overlay key.

In a photolithography process for forming the active contacts AC, the third key patterns KP3 formed earlier may be used as an overlay key. In an embodiment, the photolithography process may include the EUV lithography process described above. After performing the EUV lithography process, it may be determined whether the active contacts AC are misaligned by detecting diffracted light diffracted from the third key patterns KP3.

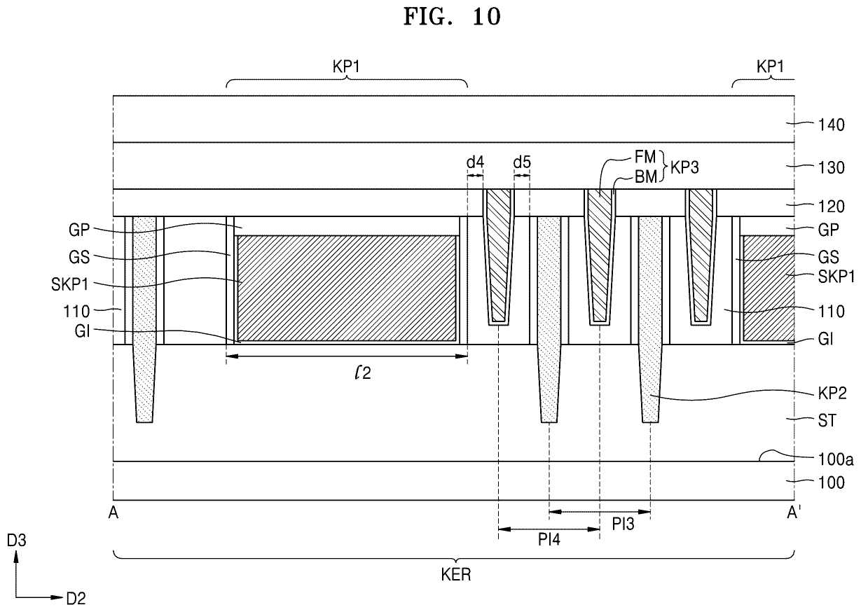

Referring to FIG. 10. a third interlayer insulating film 130 may be formed on a second interlayer insulating film 120. The first wiring layer M1 described above with reference to FIGS. 2A to 2E may be formed in the third interlayer insulating film 130. A fourth interlayer insulating film 140 may be formed on the third interlayer insulating film 130. The second wiring layer M2 described above with reference to FIGS. 2A to 2E may be formed in the fourth interlayer insulating film 140.

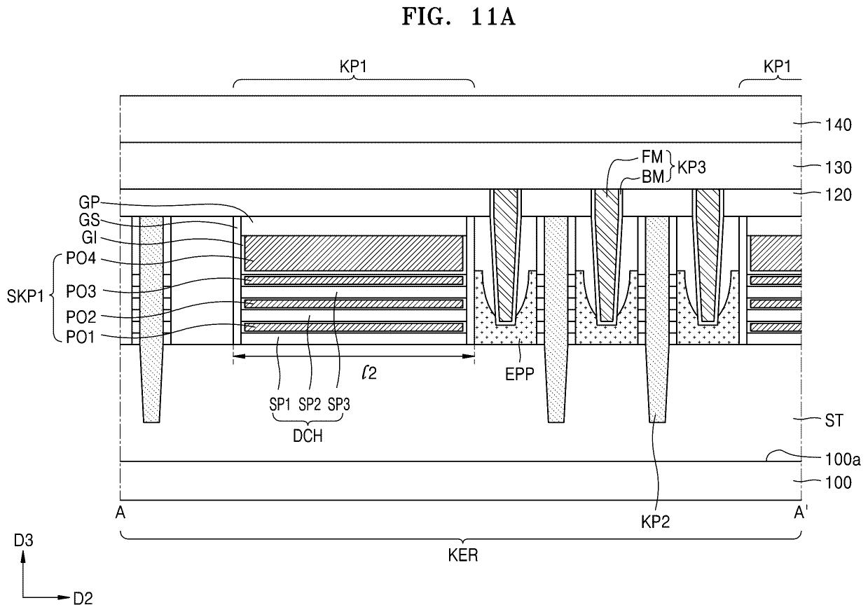

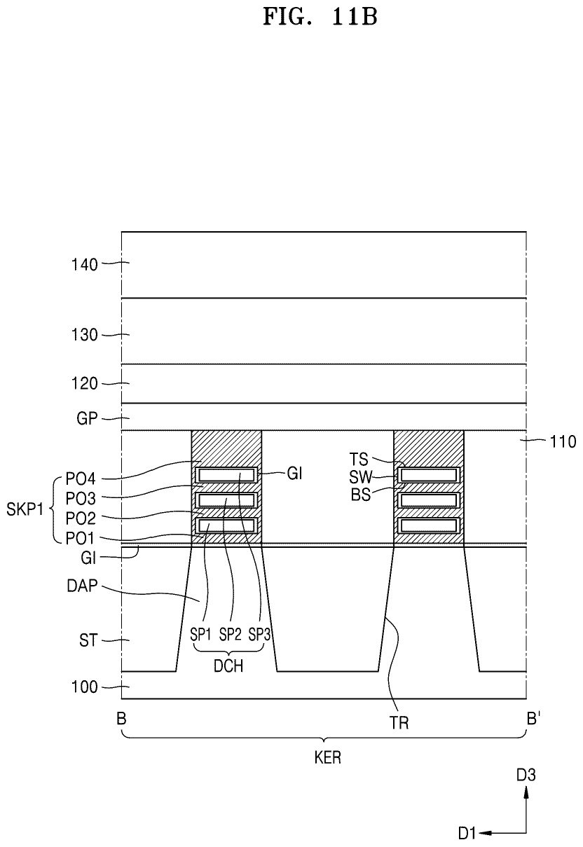

FIG. 11A is a drawing illustrating another embodiment of a semiconductor device taken along line A-A′ of FIG. 5A and FIG. 11B is a cross-sectional view from another perspective of the semiconductor device of FIG. 11A. Detailed descriptions of repeated technical features as those described above are omitted, and the differences from the above descriptions are described in detail.

Referring to FIGS. 11A and 11B, a plurality of dummy active patterns DAP may be provided in a key region KER of a substrate 100. The dummy active patterns DAP may be arranged in a first direction D1. The dummy active patterns DAP may extend in a second direction D2. The dummy active patterns DAP may be simultaneously formed with the first and second active patterns AP1 and AP2 in the logic cell region CER aforementioned. A device separation layer ST filling a trench TR between the dummy active patterns DAP may be provided.

A dummy channel pattern DCH may be provided on the dummy active patterns DAP. The dummy channel pattern DCH may include a first semiconductor pattern SP1, a second semiconductor pattern SP2, and a third semiconductor pattern SP3 that are sequentially stacked. The first to third semiconductor patterns SP1, SP2, and SP3 may be spaced apart from each other in a vertical direction (that is, a third direction D3). Each of the first to third semiconductor patterns SP1, SP2, and SP3 may include a nano sheet. In other words, the dummy channel pattern DCH may be a stack including stacked nano sheets. The dummy channel pattern DCH may be simultaneously formed with the first and second channel patterns CH1 and CH2 in the logic cell region CER aforementioned.

First subkey patterns SKP1 crossing the dummy active patterns DAP and extending in a second direction D2 may be provided. The first subkey patterns SKP1 may be simultaneously formed with the gate electrodes GE in the logic cell region CER aforementioned.

As described above, the first subkey patterns SKP1 may be arranged at the second pitch PI2 in the first direction D1. The second pitch PI2 may be less than or equal to the first pitch PI1 between the gate electrodes GE. In an embodiment, a first subkey pattern SKP1 may have a line width w2 which is less than or equal to a line width w1 of a gate electrode GE on a logic cell region CER.

The first subkey pattern SKP1 may include a first inner electrode PO1 disposed between the dummy active pattern DAP and the first semiconductor pattern SP1, a second inner electrode PO2 disposed between the first semiconductor pattern SP1 and the second semiconductor pattern SP2, a third inner electrode PO3 disposed between the second semiconductor pattern SP2 and the third semiconductor pattern SP3, and an outer electrode PO4 on the third semiconductor pattern SP3.

The first subkey pattern SKP1 may be provided on an upper surface TS, a bottom surface BS, and both side walls SW of each of the first to third semiconductor patterns SP1, SP2, and SP3. The first subkey pattern SKP1 may surround the upper surface TS, the bottom surface BS, and both the side walls SW of each of the first to third semiconductor patterns SP1, SP2, and SP3. In other words, a lower key structure according to the embodiment may include a structure of a three-dimensional field-effect transistor.

A pair of gate spacers GS may be located on both side walls of the outer electrode PO4 of the first subkey pattern SKP1, respectively. The descriptions of the gate spacers GS may be the same as the descriptions of the gate spacers GS in the logic cell region CER aforementioned.

A gate capping pattern GP may be provided on the first subkey pattern SKP1. The description of the gate capping pattern GP may be the same as the description of the gate capping pattern GP in the logic cell region CER described above.

A gate insulating film GI may be disposed between the first subkey pattern SKP1 and the dummy channel pattern DCH. The gate insulating film GI may cover the upper surface TS, the bottom surface BS, and both the side walls SW of each of the first to third semiconductor patterns SP1, SP2, and SP3. The descriptions of the gate insulating film GI may be the same as the descriptions of the gate insulating film GI in the logic cell region CER aforementioned.

A second key pattern KP2 may be provided between a first key pattern KP1 and the first key pattern KP1 adjacent thereto. The second key pattern KP2 may include a separation structure DB in the logic cell region CER. The second key pattern KP2 may extend in a third direction D3 and, therefore, extend into the dummy active pattern DAP. The descriptions of the second key pattern KP2 may be the same as those described above in FIGS. 4A and 4B.

In an embodiment, an epi pattern EPP having a recessed upper surface RTS between a pair of second key patterns KP2 that are consecutively arranged in a second direction D2 may be provided. A third key pattern KP3 may be provided between the pair of second key patterns KP2. As an example, a bottom surface of the third key pattern KP3 may be in direct contact with the epi pattern EPP.

First to fourth interlayer insulating films 110 to 140 may be provided in the key region KER of the substrate 100. The descriptions of the first to fourth interlayer insulating films 110 to 140 may be the same as the descriptions of the first to fourth interlayer insulating films 110 to 140 in the logic cell region CER described above.

The third key patterns KP3 may pass through the first and second interlayer insulating films 110 and 120 and extend towards the substrate 100. The descriptions of the third key patterns KP3 may be the same as those described above in FIGS. 5A and 5B.

The first key pattern KP1 according to the embodiments may be formed on the dummy active pattern DAP rather than simply formed on an oxide film field (that is, the device separation layer ST). Signal regarding diffracted light may increase because the first key pattern KP1 is provided on the dummy channel pattern DCH and the epi pattern EPP of a silicon base. In addition, noise regarding diffracted light may decrease. Therefore, the key pattern KP1 according to inventive concepts may provide improved overlay measuring performance.

While aspects of inventive concepts have been particularly shown and described with reference to embodiments thereof, it will be understood that various changes in form and details may be made therein without departing from the spirit and scope of the following claims.

What is claimed is:

1. A semiconductor device comprising:
a substrate including a logic cell region and a key region;
an active pattern in the logic cell region;
a channel pattern on the active pattern;
a plurality of gate electrodes extending on the channel pattern in a first direction, the plurality of gate electrodes being spaced apart from each other in a second direction perpendicular to the first direction;
a device separation layer on the key region; and
first key patterns corresponding to the plurality of gate electrodes on the device separation layer, wherein
each of the first key patterns includes a plurality of first subkey patterns spaced apart from each other in the first direction and extending in the second direction.

2. The semiconductor device of claim 1, wherein
the plurality of gate electrodes include a gate electrode,
the plurality of first subkey patterns include a first subkey pattern,
a ratio of a length to a width of the first subkey pattern is smaller than a ratio of a length to a width of the gate electrode.

3. The semiconductor device of claim 1, wherein
the plurality of first subkey patterns include a first subkey pattern, and
a length of the first subkey pattern is greater than a pitch between the plurality of gate electrodes.

4. The semiconductor device of claim 1, wherein
the plurality of first subkey patterns include a first subkey pattern, and
a length of the first subkey pattern is twice or more a pitch between the plurality of gate electrodes.

5. The semiconductor device of claim 1, wherein
the plurality of gate electrodes include a gate electrode,
the plurality of first subkey patterns include a first subkey pattern,
a length of the first subkey pattern is equal to a sum of n times a pitch between the plurality of gate electrodes and a width of the gate electrode, and
n is an integer of 2 or more.

6. The semiconductor device of claim 1, wherein
the plurality of gate electrodes include a gate electrode,
the plurality of first subkey patterns include a first subkey pattern, and
a width of the first subkey pattern is equal to or less than a width of the gate electrode.

7. The semiconductor device of claim 1, wherein
the plurality of gate electrodes include a gate electrode,
the plurality of first subkey patterns include a first subkey pattern,
a length of the gate electrode is equal to a sum of m times a pitch between the plurality of first subkey patterns and a width of the first subkey pattern, and
m is an integer of 5 or more.

8. The semiconductor device of claim 1, further comprising:
first separation structures and second separation structures spaced apart from each other with the plurality of gate electrodes therebetween, the first separation structures and the second separation structures each extending into the active pattern in a third direction, the third direction being perpendicular to the first direction and the second direction; and
two second key patterns extending into the device separation layer in the third direction, the two second key patterns being spaced apart from each other with the first key pattern therebetween, and the two second key patterns corresponding to the first separation structures and the second separation structures.

9. The semiconductor device of claim 8, wherein
the first key patterns include a first key pattern,
the two second key patterns include a second key pattern,
a spacing between the first key pattern and the second key pattern is equal to a spacing between the plurality of gate electrodes.

10. The semiconductor device of claim 8, further comprising:
a third key pattern, wherein
the first key patterns include a first key pattern,
the two second key patterns include a second key pattern,
the third key pattern is between the first key pattern and the second key pattern, and the first key pattern and the third key pattern are located at different levels.

11. The semiconductor device of claim 8, wherein
the first key pattern further includes a plurality of capping patterns respectively located on the plurality of first subkey patterns, and
upper surfaces of the plurality of capping patterns are coplanar with upper surfaces of the two second key patterns.

12. A semiconductor device comprising:
a substrate including a key region;
a device separation layer on the key region;
a plurality of first key patterns on the device separation layer; and
a plurality of second key patterns between adjacent first key patterns among the plurality of first key patterns, each of the plurality of second key patterns extending in a first direction, wherein
each of the plurality of first key patterns includes a plurality of first subkey patterns spaced apart from each other in the first direction and extending in a second direction, and
the second direction is perpendicular to the first direction;
a first spacer on a side wall of a corresponding one of the plurality of first subkey patterns; and
a capping pattern on the corresponding one of the plurality of first subkey patterns.

13. The semiconductor device of claim 12, further comprising:
a second spacer, wherein
each second key pattern among the plurality of second key patterns includes a second subkey pattern extending into the device separation layer in a third direction,
the third direction is perpendicular to the first direction and the second direction; and
the second spacer on a side wall of the second subkey pattern.

14. The semiconductor device of claim 12, wherein
the plurality of first subkey patterns include a first subkey pattern,
the plurality of second key patterns include a second key pattern, and
a ratio of a length to a width of the first subkey pattern is smaller than a ratio of a length to a width of the second key pattern.

15. The semiconductor device of claim 12, wherein
the plurality of first subkey patterns include a first subkey pattern, and
a length of the first subkey pattern is greater than a pitch between the plurality of second key patterns.

16. The semiconductor device of claim 12, wherein
the plurality of first subkey patterns include a first subkey pattern,
the plurality of second key patterns include a second key pattern,
a length of the first subkey pattern is equal to a sum of n times a pitch between the plurality of second key patterns and a width of the second key pattern, and
n is an integer between 2 and 6.

17. The semiconductor device of claim 12, wherein
the plurality of first subkey patterns include a first subkey pattern,
the plurality of second key patterns include a second key pattern,
a length of the second key pattern is equal to a sum of m times a pitch between the plurality of first subkey patterns and a width of the first subkey pattern, and
m is an integer of 5 or more.

18. A semiconductor device comprising:
a substrate including a key region;
a device separation layer on the key region;
a plurality of lower key patterns on the device separation layer;
a first interlayer insulating film between the plurality of lower key patterns;
a second interlayer insulating film on the plurality of lower key patterns and the first interlayer insulating film; and
a plurality of upper key patterns between adjacent lower key patterns among the plurality of lower key patterns, the plurality of upper key patterns extending into the second interlayer insulating film, each of the plurality of upper key patterns extending in a first direction, wherein
each of the plurality of lower key patterns includes a plurality of first subkey patterns spaced apart from each other in the first direction and extending in a second direction, and
the second direction is perpendicular to the first direction.

19. The semiconductor device of claim 18, wherein each of the plurality of upper key patterns includes a conductive pattern and a barrier pattern surrounding the conductive pattern.

20. The semiconductor device of claim 18, wherein
the plurality of lower key patterns include a lower key pattern,
the plurality of upper key patterns include an upper key pattern,
a bottom surface of the lower key pattern is closer to the substrate compared to a distance between a bottom surface of the upper key pattern and the substrate.
